(19) United States
(12) Patent Application Publication
(10) Pub. No.: US 2012/0313801 A1
(43) Pub. Date: Dec. 13, 2012

(54) AD CONVERTER

(75) Inventors: Shinroku MAEJIMA, Kanagawa (JP); Yoshinori Tokioka, Kanagawa (JP)

(73) Assignee: RENESAS ELECTRONICS CORPORATION

(21) Appl. No.: 13/487,669

(22) Filed: Jun. 4, 2012

(30) Foreign Application Priority Data
Jun. 10, 2011 (JP) 2011-129797

(51) Int. Cl. H03M 1/12

(52) U.S. Cl. 341/155

(57) ABSTRACT

To provide a highly accurate and small AD converter. The AD converter converts an analog voltage Vin into a digital code DC of N-bit, and includes memory blocks MB1 to MB (2^{N}−1). Each memory block MB (2ⁿ−1) includes (2ⁿ−1) memory cells 1 for an MRAM. After stored data of the memory cell 1 is reset to “0”, an analog current Iin proportional to the analog voltage Vin is shunted to the (2ⁿ−1) bit lines BL of the each memory block MB (2ⁿ−1). Stored data of the memory cells 1 of the memory blocks MB1 to MB (2^{N}−1) is read to generate the digital code DC. Accordingly, a ladder resistance is unnecessary.

### CROSS-REFERENCE TO RELATED APPLICATION

The disclosure of Japanese Patent Application No. 2011-129797 filed on Jun. 10, 2011 including the specification, drawings and abstract is incorporated herein by reference in its entirety.

### BACKGROUND

The present invention relates to AD converters and, in particular, to an AD converter which converts an analog voltage into a digital code.

### DESCRIPTION OF THE RELATED ART

An AD (Analog to Digital) converter in the related art compares an input analog voltage with a plurality of reference voltages, and generates a digital code based on a comparison result. The reference voltages are generated by dividing a power supply voltage using a ladder resistor. The ladder resistor is formed of a polycrystalline silicon film, and includes a plurality of series-connected resistive elements (for example, refer to Japanese Patent Laid-Open No. 2010-74035 (Patent Document 1)).

In order to improve accuracy of the above-described AD converter, it is necessary to increase a bit number of the AD converter and to reduce variation in a resistance value of each resistive element of the ladder resistor. In order to increase the bit number of the AD converter by 2 bits, it is necessary to quadruple the number of resistive elements of the ladder resistor. In addition, in order to reduce variation in the resistance value of the each resistive element of the ladder resistor, it is necessary to increase a size of the ladder resistor. Accordingly, there is a problem in which a layout area becomes large when accuracy of the AD converter in the related art is improved.

Therefore, a main object of the present invention is to provide a highly accurate and small AD converter.

### SUMMARY

An AD converter according to the present invention is the AD converter which converts an input analog voltage into a digital code having a first to an N-th (however, N is an integer of 2 or more) data signals, and the AD converter includes a first to a (2^{N}−1)-th memory blocks. A (2ⁿ−1)-th (however, n is any of integers from 1 to N) memory block includes: (2ⁿ−1) bit line (s); and (2ⁿ−1) memory cell (s) which is(are) provided corresponding to the (2ⁿ−1) bit line(s), respectively, and in which each stored data is changed from a first logical value to a second logical value when a current exceeding a predetermined threshold current is caused to flow in the corresponding bit line(s). The AD converter is further provided with: a current generation circuit which generates an analog current of a level in accordance with the analog voltage; a write circuit which is provided corresponding to the (2ⁿ−1)-th memory block, and which shunts the analog current to the corresponding (2ⁿ−1) bit line(s) at the time of a write operation; and a read circuit which reads stored data of memory cells of the first to the (2^{N}−1)-th memory blocks to generate a digital code at the time of a read operation.

In addition, an AD converter according to the present invention is the AD converter which converts an input analog voltage into a digital code having a first to an N-th (however, N is an integer of 2 or more) data signals, and the AD converter includes: a first to a (2^{N}−1)-th bit lines; a first to a (2^{N}−1)-th memory cells which are provided corresponding to the first to the (2^{N}−1)-th bit lines, respectively, and in which each stored data is changed from a first logical value to a second logical value when a current exceeding a predetermined threshold current is caused to flow in the corresponding bit lines; and a first to a (2^{N}−1)-th current generation circuits which generate a first to a (2^{N}−1)-th analog currents of levels in accordance with the analog voltage, respectively. The levels of the first to the (2^{N}−1)-th analog currents sequentially change in a stepwise manner. The AD converter is further provided with: a write circuit which causes the first to the (2^{N}−1)-th analog currents to flow in the first to the (2^{N}−1)-th bit lines, respectively at the time of a write operation; and a read circuit which reads stored data of the first to the (2^{N}−1)-th memory cells to generate a digital code at the time of a read operation.

In addition, a still other AD converter according to the present invention is the AD converter which converts an input analog voltage into a digital code having a first to an N-th (however, N is an integer of 2 or more) data signals, and the AD converter includes a first to an N-th memory blocks. An n-th (however, n is any of integers from 1 to N) memory block includes: 2ⁿ⁻¹ bit lines each of which has one end being connected to each other; and 2ⁿ⁻¹ memory cells which are provided corresponding to the 2ⁿ⁻¹ bitlines, respectively, and in each of which stored data is changed from a first logical value to a second logical value when a current exceeding a predetermined threshold current is caused to flow in the corresponding bit lines. The AD converter is further provided with: a current generation circuit which generates an analog current of a level in accordance with the analog voltage; a first to an N-th switches which are provided corresponding to the first to the N-th memory blocks, respectively, and each of which has one terminal being connected to each other to receive the analog current, and each of which has the other terminal being connected to the one end of the bit lines of the first to the N-th memory blocks, respectively; and a write/read circuit which controls the first to the N-th switches to generate a digital code. The write/read circuit includes: a first step of switching on an n-th switch to shunt the analog current to 2ⁿ⁻¹ bit lines of the n-th memory block; a second step of switching off the n-th switch to read stored data of a memory cell of the n-th memory block; and a third step of switching off the n-th switch when the read stored data is a first logical value, and switching on the n-th switch when the read stored data is a second logical value, and the write/read circuit repeats the first to the third steps from n=N to n=1, and generates a digital code based on whether each of the first to the N-th switches is turned on or turned off.

In an AD converter according to the present invention, a memory cell is utilized in which stored data changes from a first logical value to a second logical value when a current exceeding a threshold current is caused to flow in a bit line. Accordingly, a ladder resistor becomes unnecessary, and a highly accurate and small AD converter can be achieved.

### BRIEF DESCRIPTION OF THE DRAWINGS

FIG. 1 is a circuit block diagram showing a configuration of a flash-type AD converter according to an embodiment 1 of the present invention;

FIG. 2 is a circuit diagram showing a configuration of a memory cell shown in FIG. 1;

FIG. 3 is a circuit diagram showing a configuration of a current generation circuit shown in FIG. 1;

FIG. 4 is a circuit block diagram showing a configuration of a flash-type AD converter according to an embodiment 2 of the present invention;

FIG. 5 is a circuit diagram showing a configuration of a memory cell shown in FIG. 4;

FIG. 6 is a circuit diagram showing a modified example of the embodiment 2;

FIG. 7 is a circuit diagram showing other modified example of the embodiment 2;

FIG. 8 is a circuit block diagram showing a configuration of a flash-type AD converter according to an embodiment 3 of the present invention;

FIG. 9 is a circuit block diagram showing a modified example of the embodiment 3;

FIG. 10 is a circuit block diagram showing a configuration of a sequential conversion type AD converter according to an embodiment 4 of the present invention; and

FIG. 11 is a circuit block diagram showing a modified example of the embodiment 4.

### DETAILED DESCRIPTION

### Embodiment 1

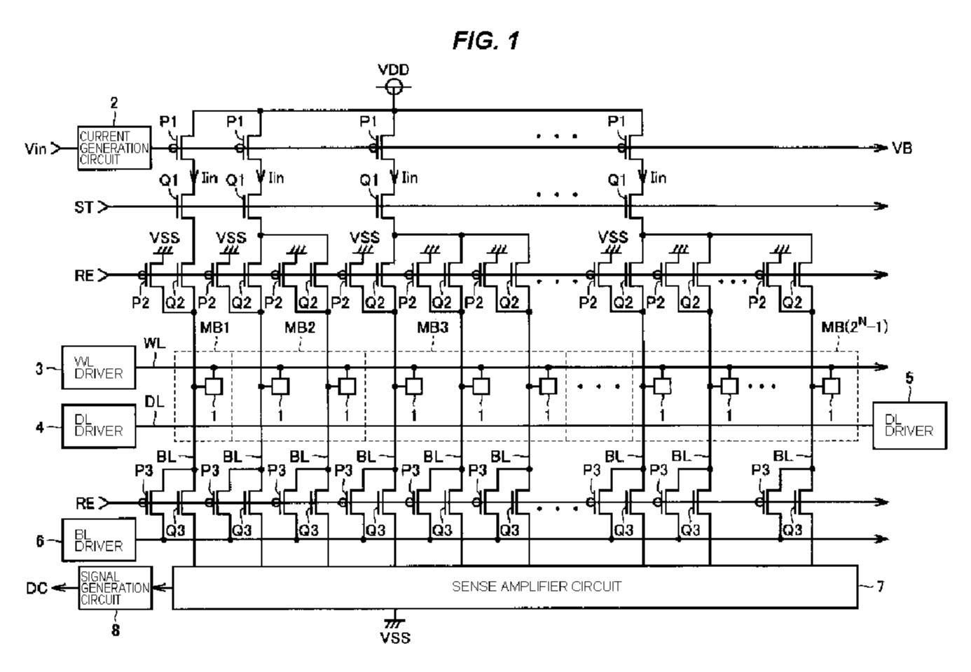

A flash-type AD converter according to an embodiment 1 of the present invention is, as shown in FIG. 1, the AD converter which converts an input analog voltage Vin into a digital code DC having a first to an N-th (however, N is an integer of 2 or more) data signals, and the AD converter includes a first to a (2^{N}−1)-th memory blocks MB1 to MB (2^{N}−1).

A (2ⁿ−1)-th (however, n is any of integers from 1 to N) memory block MB (2ⁿ−1) includes: (2ⁿ−1) bit line(s) BL; and (2ⁿ−1) memory cell (s) 1 provided corresponding to the (2ⁿ−1) bit line(s) BL, respectively. That is, the numbers of bit lines BL of the memory blocks MB1 to MB (2^{N}−1) are 1, 2, 3, 4, . . . , (2^{N}−2), and (2^{N}−1), respectively. In addition, the numbers of memory cells 1 of the memory blocks MB1 to MB (2^{N}−1) are 1, 2, 3, 4, . . . , (2^{N}−2), and (2^{N}−1), respectively. Each bit line BL extends in a vertical direction in FIG. 1.

In addition, a word line WL and a digit line DL are provided common to the first to the (2^{N}−1)-th memory blocks MB1 to MB (2^{N}−1). Each of the word line WL and the digit line DL extends in a horizontal direction in FIG. 1, and intersects with the each bit line BL. The memory cell 1 is arranged at each intersecting portion of the word line WL and the digit line DL, and the bit lines BL.

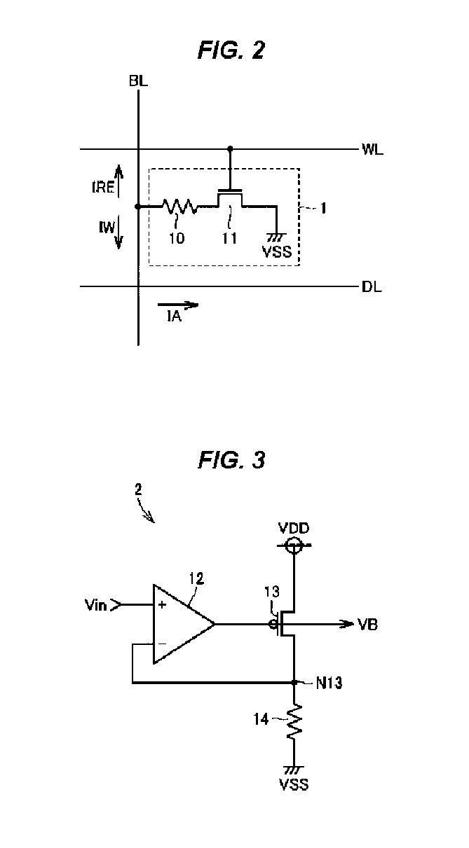

The memory cell 1 is the memory cell for a conventional type MRAM (magnetoresistive random access memory). The memory cell 1, as shown in FIG. 2, includes a series-connected magnetoresistive element 10 and an N-channel MOS transistor 11 between the corresponding bit line BL and a line of a ground voltage VSS. A gate of the N-channel MOS transistor 11 is connected to the corresponding word line WL. The memory cell 1 is provided near the corresponding word line WL, digit line DL, and bit line BL.

In the memory cell 1, it is possible to rewrite a resistance value of the magnetoresistive element 10 to a desired resistance value of a high value and a low value by causing a current to flow in both the bit line BL and the digit line DL to thereby give a magnetic field to the magnetoresistive element 10. The memory cell 1 can be caused to store 1-bit data by associating a low value state of the resistance value of the magnetoresistive element 10 with data “0”, and by associating a high value state of the resistance value of the magnetoresistive element 10 with data “1”.

Here, operations of the memory cell 1 will be described. At the time of a reset operation, for example, an activation current IA of a predetermined value is caused to flow in the digit line DL from a left side toward a right side in FIG. 2. When in this state, for example, a reset current IRE of a value exceeding a predetermined threshold current is caused to flow in the bit line BL from a lower side toward an upper side in FIG. 2, a resistance value of the magnetoresistive element 10 is reset to a low value.

At the time of a write operation, for example, the activation current IA of the predetermined value is caused to flow in the digit line DL form the left side toward the right side in FIG. 2. When in this state, for example, a write current IW of a value exceeding the predetermined threshold current is caused to flow in the bit line BL from the upper side toward the lower side in FIG. 2, the resistance value of the magnetoresistive element 10 is rewritten from a low value to a high value. However, when a value of the write current IW flowed in the bit line BL is smaller than the predetermined threshold current, the resistance value of the magnetoresistive element 10 is maintained so as to be the low value.

At the time of a read operation, the word line WL is raised to an “H” level of a selection level, and the N-channel MOS transistor 11 is turned on. In this state, a predetermined read voltage VR is applied to the bit line BL, and a read current IR flows in the line of the ground voltage VSS from the bit line BL via the magnetoresistive element 10 and the N-channel MOS transistor 11. When the read current IR is smaller than a predetermined reference current, the resistance value of the magnetoresistive element 10 is determined to be the high value, and the data “1” is read from the memory cell 1. In addition, when the read current IR is larger than the predetermined reference current, the resistance value of the magnetoresistive element 10 is determined to be the low value, and the data “0” is read from the memory cell 1.

Returning to FIG. 1, the AD converter includes: a current generation circuit 2; a WL driver 3; DL drivers 4 and 5; a BL driver 6; a sense amplifier circuit 7; and a signal generation circuit 8. In addition, the AD converter includes: a P-channel MOS transistor P1 and an N-channel MOS transistor Q1 which are provided corresponding to each memory block MB; and P-channel MOS transistors P2 and P3 and N-channel MOS transistors Q2 and Q3 which are provided corresponding to each bit line BL.

One end of the bit line BL of the each memory block MB is connected to a line of a power supply voltage VDD via the corresponding N-channel MOS transistors Q2 and Q1 and the P-channel MOS transistor P1, and is connected to the line of the ground voltage VSS via the P-channel MOS transistor P2. Drains of the (2ⁿ−1) N-channel MOS transistors Q2 of the memory block MB (2ⁿ−1) are all being connected to sources of the corresponding N-channel MOS transistors Q1.

In addition, another end of the bit line BL of the each memory block MB is connected to the sense amplifier circuit 7 via the corresponding N-channel MOS transistor Q3, and is connected to an output node of the BL driver 6 via the corresponding P-channel MOS transistor P3. The current generation circuit 2 generates an analog current Iin of a value proportional to the input analog voltage Vin, and causes the analog current Iin to flow in the each P-channel MOS transistor P1.

The current generation circuit 2, as shown in FIG. 3, includes an operation amplifier 12, a P-channel MOS transistor 13, and a resistive element 14. The P-channel MOS transistor 13 and the resistive element 14 are series-connected between the line of the power supply voltage VDD and the line of the ground voltage VSS. A non-inverting input terminal (+terminal) of the operation amplifier 12 receives the analog voltage Vin, an inverting input terminal (−terminal) thereof is connected to a drain (node N13) of the P-channel MOS transistor 13, and an output terminal thereof is connected to a gate of the P-channel MOS transistor 13.

The operation amplifier 12 controls a gate voltage VB of the P-channel MOS transistor 13 so that a voltage of the node N13 coincides with the analog voltage Vin. If a resistance value of the resistive element 14 is set to R, a current I flowing in the P-channel MOS transistor 13 and the resistive element 14 is expressed as I=Vin/R.

Returning to FIG. 1, the gate voltage VB of the P-channel MOS transistor 13 is applied to a gate of the each P channel MOS transistor P1. Accordingly, the analog current Iin of the value proportional to the analog voltage Vin flows in the each P-channel MOS transistor P1.

A gate of the each N-channel MOS transistor Q1 receives a start signal ST. When the start signal ST is at an “L” level of a deactivation level, the N-channel MOS transistor Q1 is turned off, and the analog current Iin is blocked. When the start signal ST is caused to be at an “H” level of an activation level, the N-channel MOS transistor Q1 is turned on, and the analog current Iin is caused to flow in the each memory block MB.

The analog current Iin flowed in the (2ⁿ−1)-th memory block MB (2ⁿ−1) is shunted to (2ⁿ−1) bit line (s) BL. The write current IW which flows in the each bit line BL is expressed as IW=Iin/(2ⁿ−1). Accordingly, the write current IW flowing in the each bit line BL indicates a maximum value Iin in the memory block MB1, decreases when n increases, and indicates a minimum value Iin/(2^{N}−1) in the memory block MB (2^{N}−1).

The WL driver 3 raises the word line WL from an “L” level of a non-selection level, to the “H” level of the selection level at the time of the read operation, and turns on the N-channel MOS transistor 11 of the each memory cell 1. This allows the resistance value of the magnetoresistive element 10 to be read. The DL drivers 4 and 5 cause the activation current IA to flow in the digit line DL at each time of the reset operation and the write operation.

Gates of the transistors P2, P3, Q2, and Q3 all receive a reset signal RE. At the time of the reset operation, the reset signal RE is caused to be the “L” level of the activation level, the N-channel MOS transistors Q2 and Q3 are turned off, and the P-channel MOS transistors P2 and P3 are turned on. As a result of this, one end of the each bit line BL is connected to the line of the ground voltage VSS via the corresponding P-channel MOS transistor P2, and the other end thereof is connected to the output node of the BL driver 6 via the corresponding P-channel MOS transistor P3. The BL driver 6 causes the reset current IRE to flow in the each bit line BL, and resets the resistance value of the each magnetoresistive element 10 to the low value at the time of the reset operation.

In addition, the reset signal RE is caused to be the “H” level of the deactivation level at the time of the write operation and the read operation, the N-channel MOS transistors Q2 and Q3 are turned on, and the P-channel MOS transistors P2 and P3 are turned off. As a result of this, one end of the each bit line BL is connected to the line of the power supply voltage VDD via the corresponding transistors Q2, Q1, and P1, and the other end thereof is connected to the sense amplifier circuit 7 via the corresponding N-channel MOS transistor Q3.

The sense amplifier circuit 7 connects the other end (lower end in FIG. 1) of the each bit line BL to the line of the ground voltage VSS at the time of the write operation, and determines whether the resistance value of the magnetoresistive element 10 of the each memory cell MC is a low value or a high value via the each bit line BL at the time of the read operation.

In addition, the sense amplifier circuit 7 generates a first to a (2^{N}−1)-th data signals D1 to D (2^{N}−1) based on the determination result. The first to the (2^{N}−1)-th data signals D1 to D (2^{N}−1) correspond to the first to the (2^{N}−1)-th memory blocks MB1 to MB (2^{N}−1), respectively. The sense amplifier circuit 7 defines, for example, as “1” a data signal D corresponding to the memory block MB in which the resistance value of the magnetoresistive element 10 has changed from the low value to the high value, and defines, for example, as “0” a data signal D corresponding to the memory block MB in which the resistance value of the magnetoresistive element 10 has remained to be the low value. Accordingly, a first to a (2^{N}−1)-th data signals DA1 to DA (2^{N}−1) are defined, for example, as 111100 . . . 0, and serve as a thermometer code.

The signal generation circuit 8 performs thermometer code conversion of the data signals DA1 to DA (2^{N}−1) generated by the sense amplifier circuit 7, and generates a data code DC having a first to an N-th data signals DB1 to DBN.

Next, operations of the AD converter will be described briefly. First, the reset signal RE is caused to be the “L” level of the activation level, and the N-channel MOS transistors Q2 and Q3 are turned off, and the P-channel MOS transistors P2 and P3 are turned on. In addition, the activation current IA is caused to flow in the digit line DL by the DL drivers 4 and 5, and the reset current IRE is caused to flow in the each bit line BL by the BL driver 6, whereby the resistance value of the magnetoresistive element 10 of the each memory cell 1 is reset to be the low value.

At the time of the write operation, the reset signal RE is caused to be the “H” level of the deactivation level, the N-channel MOS transistors Q2 and Q3 are turned on, and the P-channel MOS transistors P2 and P3 are turned off. In addition, the activation current IA is caused to flow in the digit line DL by the DL drivers 4 and 5, and the start signal ST is raised to the “H” level of the activation level, and the analog current Iin proportional to the input analog voltage Vin is caused to flow in the each memory block MB.

The analog current Iin flows in the one bit line BL in the first memory block MB1, the analog current Iin is shunted to the two bit lines BL in the second memory block MB2, and the analog current Iin is shunted to the (2^{N}−1) bit lines BL in the (2^{N}−1)-th memory block MB (2^{N}−1).

In the number of memory blocks (for example, MB1 to MB4) according to a level of the analog current Iin, the current flowing in the bit line BL exceeds the threshold current, and the resistance value of the magnetoresistive element 10 of the each memory cell 1 is rewritten from the low value to the high value. In the remaining memory blocks (MB5 to MB (2^{N}−1) in this case), the current flowing in the bit line BL does not exceed the threshold current, and the resistance value of the magnetoresistive element 10 of the each memory cell 1 is maintained so as to be the low value.

At the time of the read operation, the reset signal RE is caused to be the “H” level of the deactivation level, the N-channel MOS transistors Q2 and Q3 are turned on, and the P-channel MOS transistors P2 and P3 are turned off. In addition, the start signal ST is lowered to the “L” level of the deactivation level. As a result of this, each transistor Q1 is turned off, and supply of the analog current Iin to the each memory block MB is stopped. In addition, the digit line DL is maintained, for example, so as to be the power supply voltage VDD by the DL drivers 4 and 5, and thus supply of the current to the digit line DL is stopped.

Next, the word line WL is raised to the “H” level of the selection level by the WL driver 3, and the N-channel MOS transistor 11 of the each memory cell 1 is turned on. In addition, the sense amplifier circuit 7 determines whether the resistance value of the each magnetoresistive element 10 is the low value or the high value, and generates the first to the (2^{N}−1)-th data signals DA1 to DA (2^{N}−1) based on the determination result. If the resistance values of the magnetoresistive elements 10 of the memory blocks MB1 to MB4 are converted from low values into high values, the data signals DA1 to DA (2^{N}−1) are defined as 111100 . . . 0.

Thermometer code conversion of the data signals DA1 to DA(2^{N}−1) defined as 111100 . . . 0 is performed by the signal generation circuit 8, and the data signals become the data code DC having the data signals DB1 to DBN defined as 0 . . . 0100.

In the embodiment 1, there is utilized a memory cell 1 for a conventional type MRAM, in which stored data changes from “0” to “1” when a current exceeding a threshold current is caused to flow in the bit line BL. Accordingly, a ladder resistor becomes unnecessary, and a highly accurate and small AD converter can be achieved.

It should be noted that although it is determined whether the resistance values of all the magnetoresistive elements 10 are low values or high values in the embodiment 1, the present invention is not limited to this, and one magnetoresistive element 10 may be selected as a representative in the each memory block MB and a resistance value of the selected magnetoresistive element 10 may be determined. In this case, speeding up of the read operation can be achieved.

### Embodiment 2

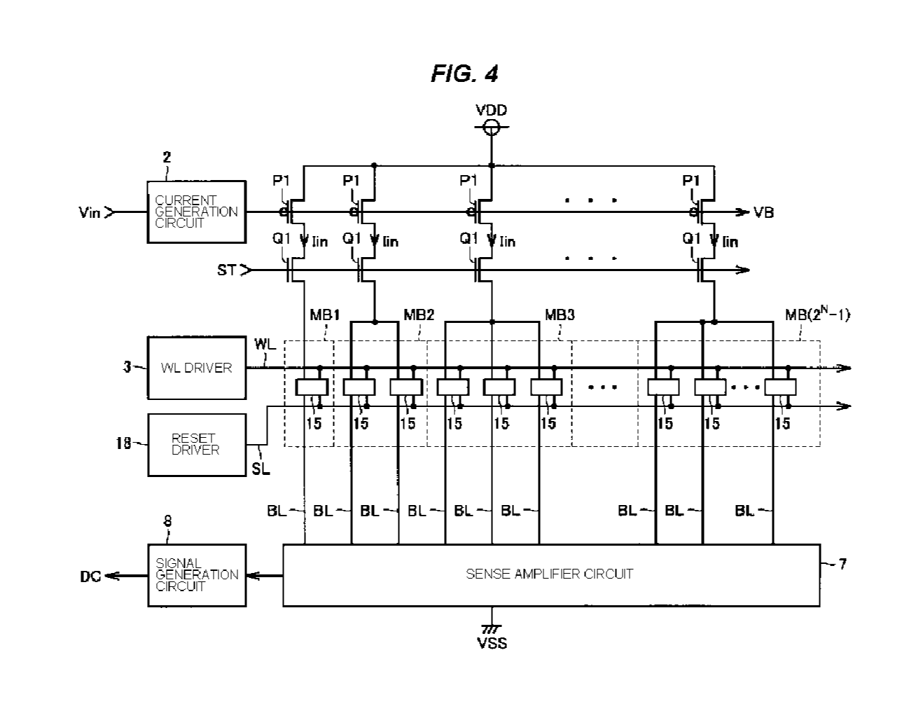

FIG. 4 is a circuit block diagram showing a configuration of a flash-type AD converter according to an embodiment 2 of the present invention, and it is the diagram compared with FIG. 1. In FIG. 4, what the AD converter differs from the AD converter in FIG. 1 is the following: the transistor P2, P3, Q2, and Q3, the digit line DL, the DL drivers 4 and 5, and the BL driver 6 are removed; the memory cell 1 is replaced by a memory cell 15; and a source line SL and a reset driver 18 are added.

The source line SL is provided common to all the memory cells 15, and is connected to an output node of the reset driver 18. The reset driver 18 applies a reset voltage VRE higher than the power supply voltage VDD to the source line SL at the time of a reset operation, and applies the ground voltage VSS to the source line SL at the time of a write operation and a read operation.

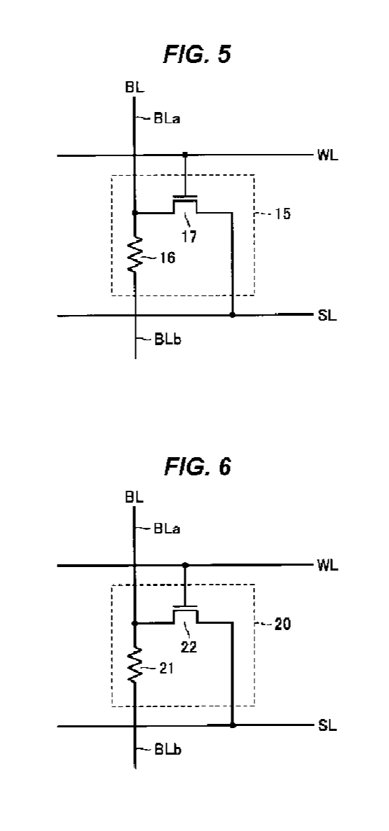

The memory cell 15 is the memory cell for an STT (spin torque transfer switching) type MRAM. The memory cell 15 includes a magnetoresistive element 16 and an N-channel MOS transistor 17 as shown in FIG. 5. The magnetoresistive element 16 is interposed in the bit line BL. That is, the bit line BL is divided into upper and lower two portions, one terminal of the magnetoresistive element 16 is connected to a source of the N-channel MOS transistor Q1 via an upper bit line BLa, and the other terminal thereof is connected to the sense amplifier circuit 7 via a lower bit line BLb. The N-channel MOS transistor 17 is connected between the one terminal of the magnetoresistive element 16 and the source line SL, and a gate of the N-channel MOS transistor 17 is connected to the word line WL.

In the memory cell 15, a resistance value of the magnetoresistive element 16 can be reset to a low value by causing a sufficiently large reset current IRE to flow in the bit line BL. In addition, in the memory cell 15, the resistance value of the magnetoresistive element 16 can be rewritten from the low value to a high value by causing a write current IW having a value smaller than the reset current IRE and larger than a predetermined threshold current, to flow in the bit line BL. The memory cell 15 can be caused to store 1-bit data by associating a low value state of the resistance value of the magnetoresistive element 16 with data “0”, and by associating a high value state of the resistance value of the magnetoresistive element 16 with data “1”.

Here, operations of the memory cell 15 will be described. At the time of the reset operation, the word line WL is raised to the “H” level of the selection level, and the N-channel MOS transistor 17 is turned on. In this state, the reset voltage VRE is applied to the source line SL, and the reset current IRE is caused to flow in the line of the ground voltage VSS from the source line SL via the N-channel MOS transistor 17, the magnetoresistive element 16, and the lower bit line BLb. As a result of this, the resistance value of the magnetoresistive element 16 is reset to the low value.

At the time of the write operation, the word line WL is lowered to the “L” level of the non-selection level, and the N-channel MOS transistor 17 is turned off. When in this state, the write current IW with the value exceeding the predetermined threshold current is caused to flow from the upper bit line BLa to the lower bit line BLb via the magnetoresistive element 16, the resistance value of the magnetoresistive element 16 is rewritten from the low value to the high value. However, when the value of the write current IW flowed in the bit line BL is smaller than the predetermined threshold current, the resistance value of the magnetoresistive element 16 is maintained so as to be the low value.

At the time of the read operation, the word line WL is raised to the “H” level of the selection level, and the N-channel MOS transistor 17 is turned on. In addition, the ground voltage VSS is applied to the source line SL. In this state, a predetermined read voltage VR is applied to the lower bit line BLb, and a read current IR flows in the source line SL from the bit line BLb via the magnetoresistive element 16 and the N-channel MOS transistor 17. When the read current IR is smaller than a predetermined reference current, the resistance value of the magnetoresistive element 16 is determined to be the high value, and the data “1” is read from the memory cell 15. In addition, when the read current IR is larger than the predetermined reference current, the resistance value of the magnetoresistive element 16 is determined to be the low value, and the data “0” is read from the memory cell 15.

Next, operations of the AD converter will be described briefly. At the time of the reset operation, the start signal ST is caused to be the “L” level, and the N-channel MOS transistor Q1 is turned off. In addition, the word line WL is raised to the “H” level of the selection level by the WL driver 3, and the N-channel MOS transistor 17 of the each memory cell 15 is turned on. In this state, the reset voltage VRE is applied to the source line SL by the reset driver 18, and the reset current IRE is caused to flow in the line of the ground voltage VSS from the source line SL via the N-channel MOS transistor 17, the magnetoresistive element 16, the bit line BLb, and the sense amplifier circuit 7. As a result of this, the resistance values of the magnetoresistive elements 16 of all the memory cells 15 are reset to be the low values.

At the time of the write operation, the ground voltage VSS is applied to the source line SL by the reset driver 18. In addition, the start signal ST is raised to the “H” level of the deactivation level, and the analog current Iin proportional to the input analog voltage Vin is caused to flow in the each memory block MB. In the number of memory blocks (for example, MB1 to MB4) according to the level of the analog current Iin, the current flowing in the bit line BL exceeds the threshold current, and the resistance value of the magnetoresistive element 16 of the each memory cell 15 is rewritten from the low value to the high value. In the remaining memory blocks (MB5 to MB (2^{N}−1) in this case), the current flowing in the bit line BL does not exceed the threshold current, and the resistance value of the magnetoresistive element 16 of the each memory cell 15 is maintained so as to be the low value.

At the time of the read operation, the start signal ST is lowered to the “L” level of the deactivation level. As a result of this, each transistor Q1 is turned off, and supply of the analog current Iin to the each memory block MB is stopped. In addition, the ground voltage VSS is applied to the source line SL by the reset driver 18. Next, the word line WL is raised to the “H” level of the selection level by the WL driver 3, and the N-channel MOS transistor 17 of the each memory cell 15 is turned on. In addition, the sense amplifier circuit 7 determines whether the resistance value of the each magnetoresistive element 16 is the low value or the high value, and generates the first to the (2^{N}−1)-th data signals DA1 to DA (2^{N}−1) based on the determination result. If the resistance values of the magnetoresistive elements 16 of the memory blocks MB1 to MB4 are converted from the low value into the high value, the data signals DA1 to DA (2^{N}−1) are defined as 111100 . . . 0.

Thermometer code conversion of the data signals DA1 to DA(2^{N}−1) defined as 111100 . . . 0 is performed by the signal generation circuit 8, and the data signals become the data code DC having the data signals DB1 to DBN defined as 0 . . . 0100. The same effect as in the embodiment 1 can also be obtained in the embodiment 2.

FIG. 6 is a circuit diagram showing a modified example of the embodiment 2, and it is the diagram compared with FIG. 5. In FIG. 6, in the AD converter, the memory cell 15 is replaced by a memory cell 20. The memory cell 20 is the memory cell for PRAM (phase change RAM: phase change memory). The memory cell 20 includes a phase change element 21 and an N-channel MOS transistor 22.

The phase change element 21 includes a GST (GeSbTe) layer. When a current exceeding a threshold current is caused to flow in the phase change element 21 to heat the GST layer to not less than 600° C., the GST layer melts. A resistance value of the GST layer changes depending on how to cool it. When the current flowed in the phase change element 21 is slowly reduced to thereby cool the GST layer slowly, the GST layer becomes a crystal state of a low resistance value, and the resistance value of the phase change element 21 becomes the low value. Conversely, when the current flowed in the phase change element 21 is rapidly reduced to thereby cool the GST layer rapidly, the GST layer becomes an amorphous state of a high resistance value, and the resistance value of the phase change element 21 becomes the high value. Accordingly, the memory cell 20 can be caused to store 1-bit data by associating a low value state of the resistance value of the phase change element 21 with data “0”, and by associating a high value state of the resistance value of the phase change element 21 with data “1”.

The phase change element 21 is interposed in the bit line BL. That is, the bit line BL is divided into upper and lower two portions, one terminal of the phase change element 21 is connected to the source of the N-channel MOS transistor Q1 via the upper bit line BLa, and the other terminal thereof is connected to the sense amplifier circuit 7 via the lower bit line BLb. The N-channel MOS transistor 22 is connected between the one terminal of the phase change element 21 and the source line SL, and a gate of the N-channel MOS transistor 22 is connected to the word line WL.

At the time of the reset operation, the word line WL is raised to the “H” level of the selection level, and the N-channel MOS transistor 22 is turned on. In this state, a reset current IRE with a value exceeding the predetermined threshold current is caused to flow in the line of the ground voltage VSS from the source line SL by the reset driver 18 via the N-channel MOS transistor 22, the phase change element 21, the lower bit line BLb, and the sense amplifier circuit 7, and the reset current IRE is reduced slowly. As a result of this, the resistance value of the phase change element 21 is reset to the low value.

At the time of the write operation, the ground voltage VSS is applied to the source line SL. In addition, the word line WL is lowered to the “L” level of the non-selection level, and the N-channel MOS transistor 22 is turned off. When in this state, a write current IW with a value exceeding the predetermined threshold current is caused to flow from the upper bit line BLa to the lower bit line BLb via the phase change element 21, and the write current IW is reduced rapidly, the resistance value of the phase change element 21 is rewritten from the low value to the high value. However, when the value of the write current IW flowed in the bit line BL is smaller than the predetermined threshold current, the resistance value of the phase change element 21 is maintained so as to be the low value.

At the time of the read operation, the ground voltage VSS is applied to the source line SL. In addition, the word line WL is raised to the “H” level of the selection level, and the N-channel MOS transistor 22 is turned on. In this state, a predetermined read voltage VR is applied to the lower bit line BLb by the sense amplifier circuit 7, and a read current IR flows in the source line SL from the bit line BLb via the phase change element 21 and the N-channel MOS transistor 22. When the read current IR is smaller than a predetermined reference current, the resistance value of the phase change element 21 is determined to be the high value, and when the read current IR is larger than the predetermined reference current, the resistance value of the phase change element 21 is determined to be the low value. Since other configurations and operations are the same as in the AD converter of FIG. 4, a description thereof will not be repeated.

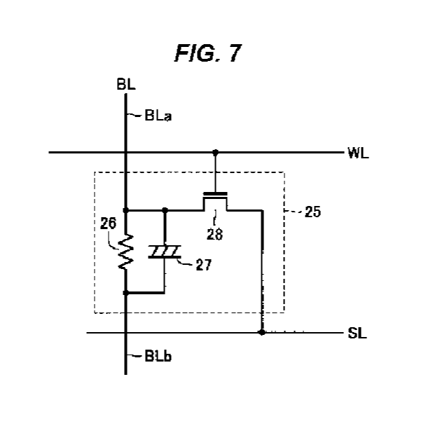

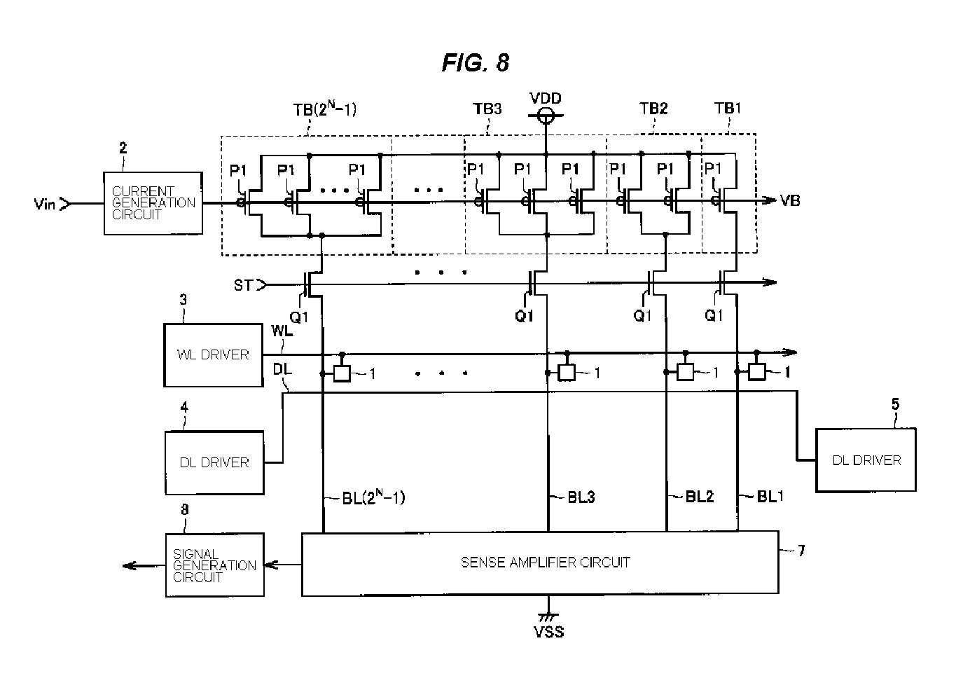

FIG. 7 is a circuit diagram showing other modified example of the embodiment 2, and it is the diagram compared with FIG. 5. In FIG. 7, in the AD converter, the memory cell 15 is replaced by a memory cell 25. The memory cell 25 is the memory cell for FeRAM (Ferroelectric RAM: ferroelectric memory). The memory cell 25 includes a resistive element 26, a ferroelectric element 27, and an N-channel MOS transistor 28.

The resistive element 26 is interposed in the bit line BL. That is, the bit line BL is divided into upper and lower two portions, one terminal of the resistive element 26 is connected to the source of the N-channel MOS transistor Q1 via the upper bit line BLa, and the other terminal thereof is connected to the sense amplifier circuit 7 via the lower bit line BLb. The ferroelectric element 27 is connected in parallel to the resistive element 26. The N-channel MOS transistor 28 is connected between the one terminal of the resistive element 26 and the source line SL, and a gate of the N-channel MOS transistor 28 is connected to the word line WL.

The ferroelectric element 27 includes a ferroelectric layer as an PZT (lead zirconate titanate) crystal layer. The ferroelectric layer has a first polarization state and a second polarization state. In the memory cell 25, it is possible to rewrite the ferroelectric element 27 to the first polarization state or the second polarization state by causing a positive current or a negative current having a larger value than the predetermined threshold current, to flow in the bit line BL. The memory cell 25 can be caused to store 1-bit data by associating a case where the ferroelectric element 27 is in the first polarization state, with data and by associating a case where the ferroelectric element 27 is in the second polarization state, with data “1”.

At the time of the reset operation, the word line WL is raised to the “H” level of the selection level, and the N-channel MOS transistor 28 is turned on. In this state, a negative reset voltage VRE is applied to the source line SL by the reset driver 18, and a negative reset current IRE with a value exceeding the predetermined threshold current is caused to flow in the line of the ground voltage VSS from the source line SL via the N-channel MOS transistor 28, the resistive element 26, the lower bit line BLb, and the sense amplifier circuit 7. As a result of this, a negative voltage is generated between terminals of the resistive element 26, and the ferroelectric element 27 is reset to the first polarization state due to the negative voltage.

At the time of the write operation, the ground voltage VSS is applied to the source line SL. The word line WL is lowered to the “L” level of the non-selection level, and the N-channel MOS transistor 28 is turned off. When in this state, the write current IW with the value exceeding the predetermined threshold current is caused to flow from the upper bit line BLa to the lower bit line BLb via the resistive element 26, a positive voltage is generated between the terminals of the resistive element 26, and the ferroelectric element 27 is rewritten from the first polarization state to the second polarization state due to the positive voltage. However, when the value of the write current IW flowed in the bit line BL is smaller than the predetermined threshold current, the ferroelectric element 27 is maintained so as to be the first polarization state.

At the time of the read operation, the ground voltage VSS is applied to the source line SL. The word line WL is raised to the “H” level of the selection level, and the N-channel MOS transistor 28 is turned on. In this state, the predetermined read voltage VR is applied to the lower bit line BLb by the sense amplifier circuit 7, and the read current IR flows in the source line SL from the bit line BLb via a parallel coupling body of the resistive element 26 and the ferroelectric element 27, and the N-channel MOS transistor 28.

At this time, when the ferroelectric element 27 is rewritten to the second polarization state, a current for rewriting the ferroelectric element 27 to the first polarization state flows. Meanwhile, when the ferroelectric element 27 is maintained so as to be the first polarization state, the current for rewriting the ferroelectric element 27 to the first polarization state does not flow. Accordingly, when the read current IR is smaller than the predetermined reference current, the ferroelectric element 27 is determined to have been maintained so as to be the first polarization state, and when the read current IR exceeds the predetermined reference current, the ferroelectric element 27 is determined to have been rewritten to the second polarization state. Since other configurations and operations are the same as in the AD converter of FIG. 4, the description thereof will not be repeated.

### Embodiment 3

A flash-type AD converter according to an embodiment 3 of the present invention is, as shown in FIG. 8, the AD converter which converts an input analog voltage Vin into a digital code DC having a first to an N-th (however, N is an integer of 2 or more) data signals, and the AD converter includes: a first to a (2^{N}−1)-th bit lines BL1 to BL (2^{N}−1); and (2^{N}−1) memory cells 1 provided corresponding to the bit lines BL1 to BL (2^{N}−1), respectively. Each bit line BL extends in a vertical direction in FIG. 8.

In addition, the word line WL and the digit line DL are provided common to the (2^{N}−1) memory cells 1. Each of the word line WL and the digit line DL extends in a horizontal direction in FIG. 8, and intersects with the each bit line BL. The memory cell 1 is arranged at each intersecting portion of the word line WL and the digit line DL, and the bit line BL. A configuration and operations of the memory cell 1 are just as shown in FIG. 2.

In addition, the AD converter includes: the N-channel MOS transistor Q1 provided corresponding to the each bit line BL; and a first to a (2^{N}−1)-th transistor blocks TB1 to TB (2^{N}−1) provided corresponding to the first to the (2^{N}−1)-th bit lines BL1 to BL (2^{N}−1), respectively.

The transistor block TB (2ⁿ−1) (however, n is any of integers from 1 to N) includes (2ⁿ−1) P-channel MOS transistor(s) P1 connected in parallel. That is, the numbers of P-channel MOS transistors P1 of the transistor blocks TB1 to TB (2^{N}−1) are 1, 2, 3, 4, . . . , (2^{N}−2), and (2^{N}−1), respectively. A source of the P-channel MOS transistor P1 receives the power supply voltage VDD, and a drain thereof is connected to the sense amplifier circuit 7 via the corresponding N-channel MOS transistor Q1 and bit line BL (2ⁿ−1).

It should be noted that although in the AD converter, the transistors P2, P3, Q2, and Q3 shown in FIG. 1 are also provided at the each bit line BL, and the BL driver 6 is provided common to all the bit lines BL, illustrations thereof are omitted for simplifying drawings and descriptions.

The AD converter is further provided with: the current generation circuit 2; the WL driver 3; the DL drivers 4 and 5; the sense amplifier circuit 7; and the signal generation circuit 8. The current generation circuit 2 generates an analog current Iin of a value proportional to the input analog voltage Vin, and causes the analog current Iin to flow in the each P-channel MOS transistor P1. Accordingly, the transistor block TB (2ⁿ−1) causes a current (2ⁿ−1) Iin (2ⁿ−1) times as large as the analog current Iin to flow.

A gate of the each N-channel MOS transistor Q1 receives the start signal ST. When the start signal ST is the “L” level of the deactivation level, the N-channel MOS transistor Q1 is turned off, and the analog current (2ⁿ−1) is blocked. When the start signal ST is caused to be the “H” level of the activation level, the N-channel MOS transistor Q1 is turned on, and the analog current (2ⁿ−1) is caused to flow in the bit line BL (2ⁿ−1). Accordingly, the write current IW which flows in the each bit line BL indicates a minimum value Iin in the bit line BL1, increases when n increases, and indicates a maximum value (2^{N}−1) Iin in the bit line BL (2^{N}−1).

The WL driver 3 raises the word line WL from the “L” level of the non-selection level to the “H” level of the selection level at the time of the read operation, and turns on the N-channel MOS transistor 11 of the each memory cell 1. This allows the resistance value of the magnetoresistive element 10 to be read. The DL drivers 4 and 5 cause the activation current IA to flow in the digit line DL at the time of the reset operation and the write operation, respectively.

The sense amplifier circuit 7 connects the other end (lower end in FIG. 8) of the each bit line BL to the line of the ground voltage VSS at the time of the write operation, and determines whether the resistance value of the magnetoresistive element 10 of the each memory cell MC is a low value or a high value via the each bit line BL at the time of the read operation.

In addition, the sense amplifier circuit 7 generates a first to a (2^{N}−1)-th data signals D1 to D (2^{N}−1) based on the determination result. The first to the (2^{N}−1)-th data signals D1 to D (2^{N}−1) correspond to the (2^{N}−1)-th to the first bit lines BL (2^{N}−1) to BL1, respectively. The sense amplifier circuit 7 defines, for example, as “1” a data signal D corresponding to the memory cell 1 in which the resistance value of the magnetoresistive element 10 has changed from the low value to the high value, and defines, for example, as “0” a data signal D corresponding to the memory cell 1 in which the resistance value of the magnetoresistive element 10 has remained to be the low value. Accordingly, a first to a (2^{N}−1)-th data signals DA1 to DA (2^{N}−1) are defined, for example, as 111100 . . . 0, and serve as a thermometer code.

The signal generation circuit 8 performs thermometer code conversion of the data signals DA1 to DA (2^{N}−1) generated in the sense amplifier circuit 7, and generates a data code DC having a first to an N-th data signals DB1 to DBN.

Next, operations of the AD converter will be described briefly. First, by a BL driver which is not shown, the reset current IRE is caused to flow in the each bit line BL, and the resistance value of the magnetoresistive element 10 of the each memory cell 1 is reset to the low value. At the time of the write operation, the activation current IA is caused to flow in the digit line DL by the DL drivers 4 and 5. In addition, the start signal ST is raised to the “H” level of the activation level, and the analog current Iin proportional to the input analog voltage Vin is caused to flow in the each P-channel MOS transistor P1.

The analog current Iin flows via the first bit line BL1, an analog current 2Iin flows via the second bit line BL2, and an analog current (2^{N}−1) flows in the (2^{N}−1)-th bit line BL (2^{N}−1).

In the number of the bit lines (for example, BL (2^{N}−1) to BL (2^{N}−4)) according to the level of the analog current Iin, the current flowing in the bit line BL exceeds the threshold current, and the resistance value of the magnetoresistive element 10 of the each memory cell 1 is rewritten from the low value to the high value. In the remaining memory blocks (BL (2^{N}−5) to BL1 in this case), the current flowing in the bit line BL does not exceed the threshold current, and the resistance value of the magnetoresistive element 10 of the each memory cell 1 is maintained so as to be the low value.

At the time of the read operation, the start signal ST is raised to the “L” level of the deactivation level. As a result of this, each transistor Q1 is turned off, and supply of the analog current Iin to the each bit line BL is stopped. In addition, the digit line DL is maintained, for example, to be the power supply voltage VDD by the DL drivers 4 and 5, and supply of the current to the digit line DL is stopped.

Next, the word line WL is raised to the “H” level of the selection level by the WL driver 3, and the N-channel MOS transistor 11 of the each memory cell 1 is turned on. In addition, the sense amplifier circuit 7 determines whether the resistance value of the each magnetoresistive element 10 is the low value or the high value, and generates the first to the (2^{N}−1)-th data signals DA1 to DA (2^{N}−1) based on the determination result. If the resistance values of the magnetoresistive elements 10 of the bit lines BL (2^{N}−1) to BL (2^{N}−4) are converted from low values into high values, the data signals DA1 to DA (2^{N}−1) are defined as 111100 . . . 0.

Thermometer code conversion of the data signals DA1 to DA(2^{N}−1) defined as 111100 . . . 0 is performed by the signal generation circuit 8, and the data signals become a data code DC having the data signals DB1 to DBN defined as 0 . . . 0100. The same effect as in the embodiment 1 can also be obtained in the embodiment 3.

It should be noted that the first to the (2^{N}−1)-th transistor blocks TB1 to TB (2^{N}−1) may be replaced by the first to the (2^{N}−1)-th P-channel MOS transistors, respectively. Sizes (that is, current drive capability) of the first to the (2^{N}−1)-th P-channel MOS transistors are set to be once to (2^{N}−1) times as a size of the first P-channel MOS transistor, respectively.

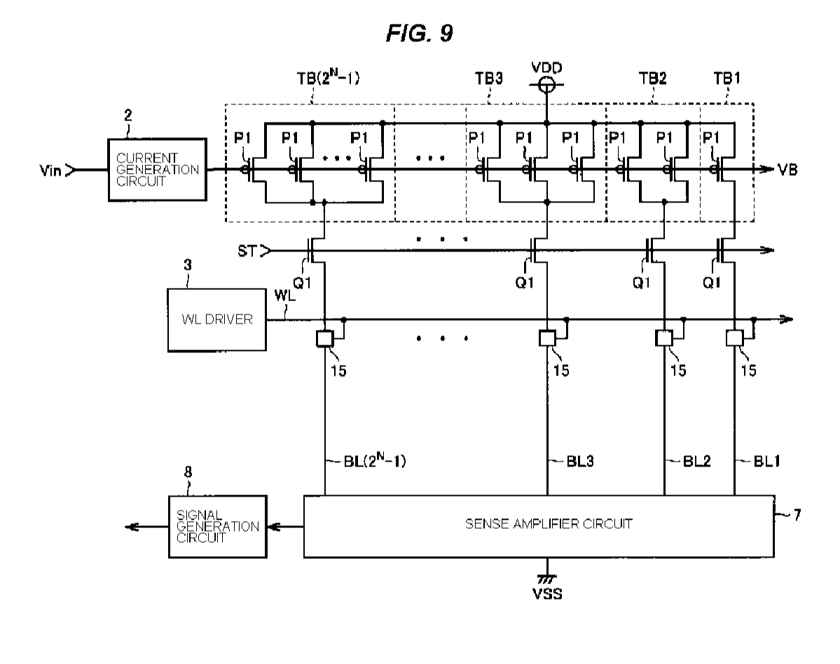

In addition, as shown in FIG. 9, the memory cell 1 may be replaced by the memory cell 15 for the STT type MRAM. In this case, the digit line DL and the DL drivers 4 and 5 become unnecessary. Further, the memory cell 15 may be replaced by the memory cell 20 for the PRAM, and the memory cell 15 may be replaced by the memory cell 25 for the FeRAM. It should be noted that in FIG. 9, illustrations of the source line SL and the reset driver 18 are omitted for simplifying the drawing.

### Embodiment 4

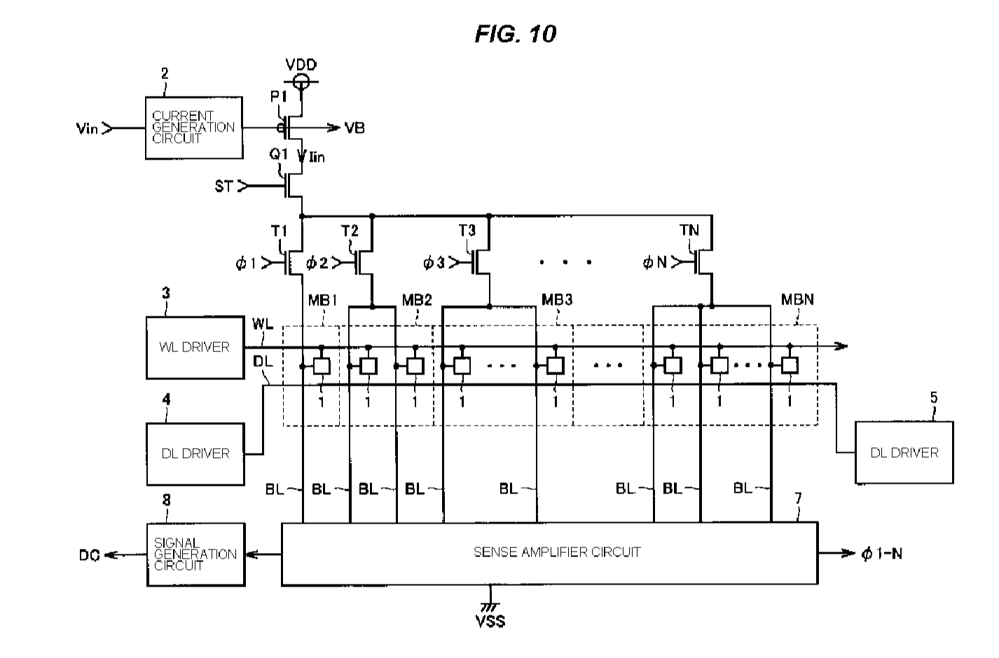

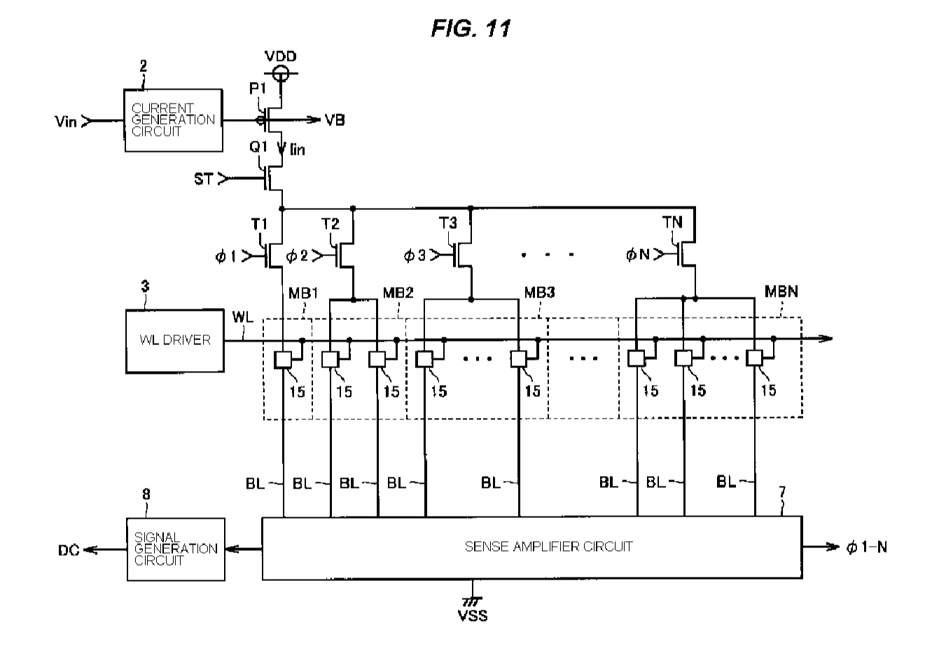

A sequential conversion type AD converter according to an embodiment 4 of the present invention is, as shown in FIG. 10, the AD converter which converts an input analog voltage Vin into a digital code DC having a first to an N-th (however, N is an integer of 2 or more) data signals, and the AD converter includes a first to an N-th memory blocks MB1 to MBN.

An n-th (however, n is any of integers from 1 to N) memory block MBn includes: 2ⁿ⁻¹ bit line (s) BL; and 2ⁿ⁻¹ memory cell (s) provided corresponding to the 2ⁿ⁻¹ bit line(s) BL, respectively. That is, the numbers of bit lines BL of the memory blocks MB1 to MBN are 1, 2, 4, 8, . . . , 2^{N-2}, and 2^{N-1}, respectively. In addition, the numbers of memory cells 1 of the memory blocks MB1 to MBN are 1, 2, 4, 8, . . . , 2^{N-2}, and 2^{N-1}, respectively. Each bit line BL extends in a vertical direction in FIG. 10. Ends on one side (upper ends in FIG. 10)) of 2ⁿ⁻¹ bit lines BL of the memory block MBn are connected to each other.

In addition, a word line WL and a digit line DL are provided common to the first to the N-th memory blocks MB1 to MBN. Each of the word line WL and the digit line DL extends in a horizontal direction in FIG. 10, and intersects with the each bit line BL. The memory cell 1 is arranged at each intersecting portion of the word line WL and the digit line DL, and the bit line BL. A configuration and operations of the memory cell 1 are just as shown in FIG. 2.

The AD converter is further provided with N-channel MOS transistors T1 to TN provided corresponding to the memory blocks MB1 to MBN, respectively. Ends on one side of the bit lines BL of the memory blocks MB1 to MBN are connected to sources of the N-channel MOS transistors T1 to TN, respectively, and drains of the N-channel MOS transistors T1 to TN are connected to each other. Gates of the N-channel MOS transistors T1 to TN receive control signals φ1 to φN from the sense amplifier circuit 7, respectively. The N-channel MOS transistors T1 to TN configure a first to an N-th switches.

It should be noted that although in the AD converter, the transistors P2, P3, Q2, and Q3 shown in FIG. 1 are also provided at the each bit line BL, and the BL driver 6 is provided common to all the bit lines BL, illustrations thereof are omitted for simplifying the drawings and the descriptions.

In addition, the AD converter is further provided with: the N-channel MOS transistor Q1; the P-channel MOS transistor P1; the current generation circuit 2; the WL driver 3; the DL drivers 4 and 5; the sense amplifier circuit 7; and the signal generation circuit 8.

The drains of the N-channel MOS transistors T1 to TN are connected to the line of the power supply voltage VDD via the N-channel MOS transistor Q1 and the P-channel MOS transistor P1. A gate of the N-channel MOS transistor Q1 receives the start signal ST. The current generation circuit 2 generates the analog current Iin with a value proportional to the input analog voltage Vin, and causes the analog current Iin to flow in the P-channel MOS transistor P1. A configuration of the current generation circuit 2 is just as shown in FIG. 3.

When the start signal ST is the “L” level of the deactivation level, the N-channel MOS transistor Q1 is turned off, and the analog current Iin is blocked. When the start signal ST is caused to be the “H” level of the activation level, the N-channel MOS transistor Q1 is turned on, and the analog current Iin is caused to flow in the memory block MB.

The analog current Iin flowed in the n-th memory block MBn is shunted to the 2ⁿ⁻¹ bit line (s) BL. The write current IW which flows in the each bit line BL is expressed as IW=Iin/2ⁿ⁻¹. Accordingly, the write current IW which flows in the each bit line BL indicates a maximum value Iin in the memory block MB1, decreases when n increases, and indicates a minimum value Iin/2^{N-1} in the memory block MBN.

The WL driver 3 raises the word line WL from the “L” level of the non-selection level to the “H” level of the selection level at the time of the read operation, and turns on the N-channel MOS transistor 11 of the each memory cell 1. This allows the resistance value of the magnetoresistive element 10 to be read. The DL drivers 4 and 5 cause the reset current IRE to flow in the digit line DL at the time of the reset operation, and cause the activation current IA to flow in the digit line DL at the time of the write operation.

The sense amplifier circuit 7 and the signal generation circuit 8 control the N-channel MOS transistors Q1, T1 to TN, etc. to generate a digital code DC. That is, the sense amplifier circuit 7 sequentially selects the memory blocks MBN to MB1 for each predetermined time. The sense amplifier circuit 7 first selects the memory block MBN, and causes signals ST and φN to be the “H” level of the activation level. As a result of this, the N-channel MOS transistors Q1 and TN are turned on, the analog current Iin is shunted to the 2^{N-1} bit lines BL, and the write current IW which flows in the each bit line BL is expressed as IW=Iin/2^{N-1}. The DL drivers 4 and 5 cause the activation current IA to flow in the digit line DL.

When the write current IW=Iin/2^{N-1} exceeds a predetermined threshold current, a resistance value of a magnetoresistive element 10 of the each memory cell MC of the memory block MBN is rewritten from a low value to a high value. In addition, when the write current IW=Iin/2^{N-1} is smaller than the predetermined threshold current, the resistance value of the magnetoresistive element 10 of the each memory cell MC of the memory block MBN is maintained so as to be the low value.

Next, the sense amplifier circuit 7 causes the signals ST and φN to be the “L” level of the deactivation level to turn off the N-channel MOS transistors Q1 and TN. The DL drivers 4 and 5 stop supply of the activation current IA to the digit line DL. In addition, the word line WL 3 raises the word line WL to the “H” level of the selection level to turn on the N-channel MOS transistor 11 of the each memory cell 1. In this state, the sense amplifier circuit 7 determines whether the resistance value of the magnetoresistive element 10 of the each memory cell 1 is the low value or the high value via the each bit line BL of the memory block MBN. When determination is completed, the word line WL 3 lowers the word line WL to the “L” level of the non-selection level to turn off the N-channel MOS transistor 11 of the each memory cell 1.

When the resistance value of the magnetoresistive element 10 of the memory block MBN is rewritten to the high value, the sense amplifier circuit 7 causes the N-th data signal DN to be “1”, causes the signal φN to be the “H” level of the activation level, and turns on the N-channel MOS transistor TN. In addition, when the resistance value of the magnetoresistive element 10 of the memory block MBN is maintained so as to be the low value, the sense amplifier circuit 7 causes the N-th data signal DN to be “0”, maintains the signal φN to be the “L” level of the deactivation level, and maintains the N-channel MOS transistor TN to be an off-state.

Next, the sense amplifier circuit 7 selects the memory block MB (N−1), and causes the signals ST and φ(N−1) to be the “H” level of the activation level. This allows the N-channel MOS transistor Q1 and T (N−1) to be turned on. When the N-channel MOS transistor TN is turned on, the analog current Iin is shunted to the 2^{N-1} bit lines BL of the memory block MBN and the 2^{N-2} bit lines BL of the memory block, and the write current IW which flows in the each bit line BL is expressed as IW=Iin/(2^{N-1}+2^{N-2}).

In addition, when the N-channel MOS transistor TN is not turned on, the analog current Iin is shunted to the 2^{N-2} bit lines BL of the memory block MB (N−1), and the write current IW which flows in the each bit line BL is expressed as IW=Iin/2^{N-2}. The DL drivers 4 and 5 cause the activation current IA to flow in the digit line DL.

When the write current IW exceeds the predetermined threshold current, a resistance value of a magnetoresistive element 10 of the each memory cell MC of the memory block MB (N−1) is rewritten from a low value to a high value. In addition, when the write current IW is smaller than the predetermined threshold current, the resistance value of the magnetoresistive element 10 of the each memory cell MC of the memory block MB (N−1) is maintained so as to be the low value.

Next, the sense amplifier circuit 7 causes the signals ST and φ(N−1) to be the “L” level of the deactivation level to turn off the N-channel MOS transistors ST and Q (N−1). The DL drivers 4 and 5 stop supply of the activation current IA to the digit line DL. In addition, the word line WL 3 raises the word line WL to the “H” level of the selection level to turn on the N-channel MOS transistor 11 of the each memory cell 1. In this state, the sense amplifier circuit determines whether the resistance value of the magnetoresistive element 10 of the each memory cell 1 is the low value or the high value via the each bit line BL of the memory block MB (N−1). When determination is completed, the word line WL 3 lowers the word line WL to the “L” level of the non-selection level to turn off the N-channel MOS transistor 11 of the each memory cell 1.

When the resistance value of the magnetoresistive element 10 of the memory block MB (N−1) is rewritten to the high value, the sense amplifier circuit 7 causes the (N−1)-th data signal D (N−1) to be “1”, causes the signal φ(N−1) to be the “H” level of the activation level, and turns on the N-channel MOS transistor Q (N−1). In addition, when the resistance value of the magnetoresistive element 10 of the memory block MB (N−1) is maintained so as to be the low value, the sense amplifier circuit 7 causes the (N−1)-th data signal D (N−1) to be “0”, maintains the signal φ(N−1) to be the “L” level of the deactivation level, and maintains the N-channel MOS transistor Q (N−1) to be an off-state. The AD converter repeats the above-described operations with respect to the memory block MBN to the memory block MB1.

The data signals D1 to DN generated by the sense amplifier circuit 7 are sent to the signal generation circuit 8. The signal generation circuit 8 generates a data code DC having the data signals D1 to DN. The same effect as in the embodiment 1 can also be obtained in the embodiment 4.

It should be noted that the memory cell 1 may be replaced by the memory cell 15 for the STT type MRAM as shown in FIG. 11. In this case, the digit line DL and the DL drivers 4 and 5 become unnecessary. Further, the memory cell 15 may be replaced by the memory cell 20 for the PRAM, and the memory cell 15 may be replaced by the memory cell 25 for the FeRAM. It should be noted that in FIG. 11, illustrations of the source line SL and the reset driver 18 are omitted for simplifying the drawing.

However, when the memory cell 15 is used, it is necessary to reset to the low value the resistance value of the magnetoresistive element 16 of the memory cell 15 of the memory block MBn after the resistance value of the magnetoresistive element 16 of the memory cell 15 of the memory block MBn is determined, and before the N-channel MOS transistor Q (n−1) of the memory block MB (n−1) is turned on.

In addition, when the memory cell 20 is used, it is necessary to reset to the low value the resistance value of the phase change element 21 of the memory cell 20 of the memory block MBn after the resistance value of the phase change element 21 of the memory cell 20 of the memory block MBn is determined, and before the N-channel MOS transistor Q (n−1) of the memory block MB (n−1) is turned on.

In addition, when the memory cell 25 is used, it is necessary to reset to the first polarization state the polarization state of the ferroelectric element 27 of the memory cell 25 of the memory block MBn after the polarization state of the ferroelectric element 27 of the memory cell 25 of the memory block MBn is determined, and before the N-channel MOS transistor Q (n−1) of the memory block MB (n−1) is turned on.

It should be considered that the embodiments disclosed herein are illustrative but not restrictive in all respects. The scope of the present invention is shown not by the above-described description but by the claims, and meaning equivalent to the claims and all modifications within the claims are intended to be embraced.

What is claimed is:

1. An AD converter which converts an input analog voltage into a digital code having a first to an N-th (however, N is an integer of 2 or more) data signals, the AD converter comprising
a first to a (2^{N}−1)-th memory blocks,
wherein a (2ⁿ−1)-th (however, n is any of integers from 1 to N) memory block includes:
(2ⁿ−1) bit line(s); and
(2ⁿ−1) memory cell(s) which is(are) provided corresponding to the (2ⁿ−1) bit line(s), respectively, and in which each stored data is changed from a first logical value to a second logical value when a current exceeding a predetermined threshold current is caused to flow in the corresponding bit line(s), and the AD converter further comprising:
a current generation circuit which generates an analog current of a level in accordance with the analog voltage;
a write circuit which is provided corresponding to the (2ⁿ−1)-th memory block, and which shunts the analog current to the corresponding (2ⁿ−1) bit line (s) at the time of a write operation; and
a read circuit which reads stored data of memory cells of the first to the (2^{N}−1)-th memory blocks to generate the digital code at the time of a read operation.

2. An AD converter which converts an input analog voltage into a digital code having a first to an N-th (however, N is an integer of 2 or more) data signals, the AD converter comprising:
a first to a (2^{N}−1)-th bit lines;
a first to a (2^{N}−1)-th memory cells which are provided corresponding to the first to the (2^{N}−1)-th bit lines, respectively, and in which each stored data is changed from a first logical value to a second logical value when a current exceeding a predetermined threshold current is caused to flow in the corresponding bit lines; and
a first to a (2^{N}−1)-th current generation circuits which generate a first to a (2^{N}−1)-th analog currents of levels in accordance with the analog voltage, respectively,
wherein the levels of the first to the (2^{N}−1)-th analog currents sequentially change in a stepwise manner, and the AD converter further comprising:
a write circuit which causes the first to the (2^{N}−1) analog currents to flow in the first to the (2^{N}−1)-th bit lines, respectively, at the time of a write operation; and
a read circuit which reads stored data of the first to the (2^{N}−1)-th memory cells to generate the digital code at the time of a read operation.

3. An AD converter which converts an input analog voltage into a digital code having a first to an N-th (however, N is an integer of 2 or more) data signals, the AD converter comprising
a first to an N-th memory blocks,
wherein an n-th (however, n is any of integers from 1 to N) memory block includes:
2ⁿ⁻¹ bit lines having ends on one side being connected to each other; and
2ⁿ⁻¹ memory cells which are provided corresponding to the 2ⁿ⁻¹ bit lines, respectively, and in which each stored data is changed from a first logical value to a second logical value when a current exceeding a predetermined threshold current is caused to flow in the corresponding bit lines, and the AD converter further comprising:
a current generation circuit which generates an analog current of a level in accordance with the analog voltage;
a first to an N-th switches which are provided corresponding to the first to the N-th memory blocks, respectively, and which have terminals on one side being connected to each other to receive the analog current, and which have other terminals being connected to ends on one side of the bit lines of the first to the N-th memory blocks, respectively; and
a write/read circuit which controls the first to the N-th switches to generate the digital code,
wherein the write/read circuit includes:
a first step of switching on an n-th switch to shunt the analog current to 2ⁿ⁻¹ bit lines of the n-th memory block;
a second step of switching off the n-th switch to read stored data of a memory cell of the n-th memory block; and
a third step of switching off the n-th switch when the read stored data is the first logical value, and switching on the n-th switch when the read stored data is the second logical value, and
the write/read circuit repeats the first to the third steps from n=N to n=1, and generates the digital code based on whether each of the first to the N-th switches is turned on or turned off.

4. The AD converter according to claim 1,
wherein each memory cell includes a magnetoresistive element provided near the corresponding bit line.

5. The AD converter according to claim 1,
wherein each memory cell includes a magnetoresistive element interposed in the corresponding bit line.

6. The AD converter according to claim 1,
wherein each memory cell includes a phase change element interposed in the corresponding bit line.

7. The AD converter according to claim 1,
wherein each memory cell includes a ferroelectric element interposed in the corresponding bit line.
